(19) United States
(12) Patent Application Publication
(10) Pub. No.: US 2025/0118651 A1
(43) Pub. Date: Apr. 10, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Seungryong OH, Suwon-si (KR); Jaejun Lee, Suwon-si (KR); Junho Lee, Suwon-si (KR)

(73) Assignee: SAMSUNG ELECTRONICS CO., LTD., Suwon-si (KR)

(21) Appl. No.: 18/733,206

(22) Filed: Jun. 4, 2024

(30) Foreign Application Priority Data
Oct. 6, 2023 (KR) 10-2023-0133234

(51) Int. Cl. H01L 23/498; H01L 23/00; H01L 23/48; H01L 25/10

(52) U.S. Cl. CPC H01L 23/49838; H01L 23/481; H01L 23/49822; H01L 24/08; H01L 25/105; H01L 24/16; H01L 24/32; H01L 24/73; H01L 2224/08238; H01L 2224/16225; H01L 2224/32225; H01L 2225/1058; H01L 2924/1815

(57) ABSTRACT

A semiconductor package includes a first semiconductor chip including a semiconductor substrate having an active surface and an inactive surface, a device layer on the active surface, first chip pads on the device layer, and a first through-electrode and a second through-electrode, where the first through-electrode and the second through-electrode penetrate the semiconductor substrate, at least one of the first chip pads is connected to the first through-electrode and at least one of the first chip pads is connected to the second through-electrode, a redistribution structure including a redistribution layer on the inactive surface of the semiconductor substrate and a redistribution via connected to the redistribution layer, contact pads on an upper surface of the redistribution structure, and a second semiconductor chip on the redistribution structure and including second chip pads connected to the contact pads.

### CROSS-REFERENCE TO RELATED APPLICATION(S)

This application is based on and claims priority to Korean Patent Application No. 10-2023-0133234, filed on Oct. 6, 2023, in the Korean Intellectual Property Office, the disclosure of which is incorporated herein by reference in its entirety.

### BACKGROUND

Example embodiments of the disclosure relate to a semiconductor package and a method of manufacturing the same.

Recently, demand for portable devices has rapidly increased in the electronic products market, and accordingly, there has been continuous demand for miniaturization and weight reduction of electronic components mounted on the products. In reducing sizes and weights of electronic components, there has also been a need to improve integration density of a semiconductor package used in an electronic component.

Various semiconductor packaging techniques have been actively researched to improve scaling and integration density of an electronic component. In particular, the development of a technique to maintain package reliability by suppressing delamination or cracks in redistribution vias despite thermal stress and external impacts during a manufacturing process or a use environment has become important.

### SUMMARY

Example embodiments provide a semiconductor package having improved reliability against thermal stress and external impacts, and a method of manufacturing the semiconductor package.

Additional aspects will be set forth in part in the description which follows and, in part, will be apparent from the description, or may be learned by practice of the presented embodiments.

According to an aspect of an example embodiment, a semiconductor package may include a first semiconductor chip including a semiconductor substrate having an active surface and an inactive surface, a device layer on the active surface, first chip pads on the device layer, and a first through-electrode and a second through-electrode, where the first through-electrode and the second through-electrode penetrate the semiconductor substrate, at least one of the first chip pads is connected to the first through-electrode and at least one of the first chip pads is connected to the second through-electrode, a redistribution structure including a redistribution layer on the inactive surface of the semiconductor substrate and a redistribution via connected to the redistribution layer, contact pads on an upper surface of the redistribution structure, and a second semiconductor chip on the redistribution structure and including second chip pads connected to the contact pads, wherein the contact pads include a first contact pad connected to the first through-electrode through the redistribution layer and a second contact pad vertically overlapping the second through-electrode, the redistribution structure further includes at least one post via penetrating the redistribution structure and connecting the second contact pad to the second through-electrode, and the first contact pad includes a contact via connected to the redistribution layer.

According to an aspect of an example embodiment, a semiconductor package may include a first redistribution structure including a first redistribution layer and a first redistribution via connected to the first redistribution layer, a semiconductor chip on the first redistribution structure and including chip pads connected to the first redistribution layer, a molding portion on the first redistribution structure and at least partially surrounding the semiconductor chip, a second redistribution structure on the molding portion, the second redistribution structure including a second redistribution layer and a second redistribution via connected to the second redistribution layer, contact pads on an upper surface of the second redistribution structure, and a first vertical connection conductor and a second vertical connection conductor on the first redistribution structure and connecting the first redistribution layer to the second redistribution layer, wherein the contact pads include a first contact pad connected to the first vertical connection conductor through the second redistribution layer, the first contact pad being horizontally offset from the first vertical connection conductor, and a second contact pad vertically overlapping the second vertical connection conductor, the first contact pad includes a contact via connected to the second redistribution layer, and the second redistribution structure further includes a post via connecting the second contact pad to the second vertical connection conductor.

According to an aspect of an example embodiment, a semiconductor package may include a first semiconductor chip including a semiconductor substrate having an active surface and an inactive surface opposite to the active surface, a device layer on the active surface, first chip pads on the device layer, and through-electrodes penetrating the semiconductor substrate and connected to the first chip pads, a redistribution structure on the inactive surface of the first semiconductor chip, a first contact pad and a second contact pad on an upper surface of the redistribution structure, wherein the second contact pad vertically overlaps one of the through-electrodes, and a second semiconductor chip on the redistribution structure and having a first second chip pad connected to the first contact pad, and a second chip pad connected to the second contact pad, wherein the redistribution structure includes a first insulating layer on an upper surface of the first semiconductor chip, a redistribution layer on the first insulating layer, a redistribution via penetrating the first insulating layer and connecting the redistribution layer to the through-electrodes, and a second insulating layer on the first insulating layer and at least partially covering the redistribution layer, the first contact pad is on the second insulating layer and includes a contact via penetrating the second insulating layer and connected to the redistribution layer, and the second contact pad is on the second insulating layer and includes a post via penetrating the first insulating layer and the second insulating layer, the post via connecting to the one through-electrode that is vertically overlapped by the second contact pad.

According to an aspect of an example embodiment, a method of manufacturing a semiconductor package may include preparing a structure including a first connection pad and a second connection pad, forming a first insulating layer on the structure with an uncured photosensitive insulating material, forming a first hole penetrating the first insulating layer and connected to the first connection pad using a photolithography process, wherein the first insulating layer is cured by the photolithography process, forming a redistribution via in the first hole, forming a redistribution layer connected to the redistribution via on the first insulating layer, forming a second insulating layer on the first insulating layer to at least partially cover the redistribution layer, curing the second insulating layer, forming a second hole penetrating the second insulating layer and connected to a region of the redistribution layer, forming a through-hole penetrating the first insulating layer and the second insulating layer using a dry etching process, the through-hole connected to the second connection pad, forming a contact via in the second hole, forming a first contact pad connected to the contact via on the second insulating layer, forming a post via in the through-hole, and forming a second contact pad connected to the post via on the second insulating layer.

According to an aspect of an example embodiment, a method of manufacturing a semiconductor package may include preparing a structure including a first connection pad and a second connection pad, forming a first insulating layer on the structure using an uncured first photosensitive insulating material, forming a first hole penetrating the first insulating layer and connected to the first connection pad using a first photolithography process, wherein the first insulating layer is cured by the first photolithography process, forming a redistribution via in the first hole, forming a redistribution layer connected to the redistribution via on the first insulating layer, forming a second insulating layer on the first insulating layer using an uncured second photosensitive insulating material to at least partially cover the redistribution layer, forming a second hole penetrating the second insulating layer and connected to the redistribution layer using a second photolithography process, wherein the second insulating layer is cured by the second photolithography process, forming a contact via in the second hole, forming a first contact pad connected to the contact via on the second insulating layer, forming a through-hole penetrating the first insulating layer and the second insulating layer using a dry etching process, the through-hole connected to the second connection pad, forming a post via in the through-hole, and forming a second contact pad connected to the post via on the second insulating layer.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a cross-sectional view illustrating a semiconductor package according to one or more example embodiments;

FIG. 2 is a plan view illustrating a semiconductor package taken along line I-I′ of FIG. 1 according to one or more example embodiments;

FIG. 3 is an enlarged diagram illustrating portion “A” of the semiconductor package illustrated in FIG. 1 according to one or more example embodiments;

FIG. 4 is a cross-sectional view illustrating a semiconductor package according to one or more example embodiments;

FIG. 5A is a cross-sectional view illustrating a semiconductor package according to one or more example embodiments;

FIG. 5B is a plan view illustrating a post via taken along line II-II′ of FIG. 5A, according to one or more example embodiments;

FIGS. 6A and 6B are cross-sectional views illustrating a semiconductor package according to one or more example embodiments;

FIGS. 7A and 7B are cross-sectional views illustrating a semiconductor package according to one or more example embodiments;

FIGS. 8A to 8E are cross-sectional views illustrating a method of manufacturing a semiconductor package according to one or more example embodiments;

FIGS. 9A to 9D are cross-sectional views illustrating a method of manufacturing a semiconductor package according to one or more example embodiments; and

FIGS. 10A to 10C are cross-sectional views illustrating a method of manufacturing a semiconductor package according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

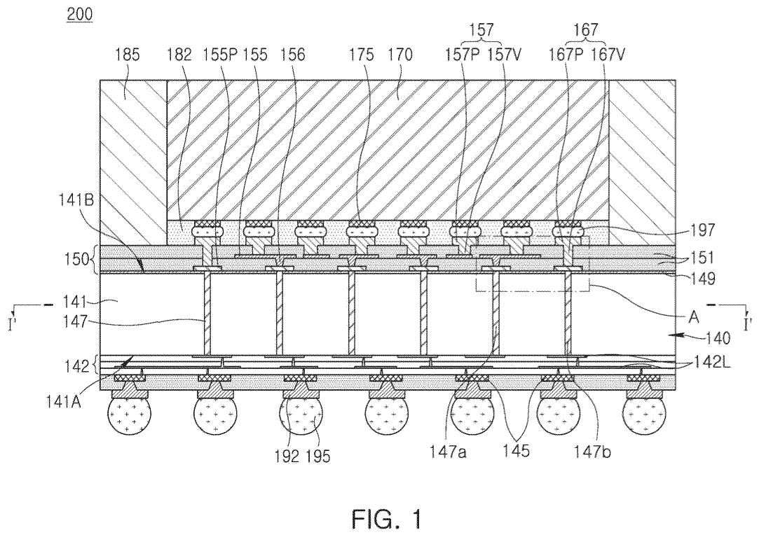

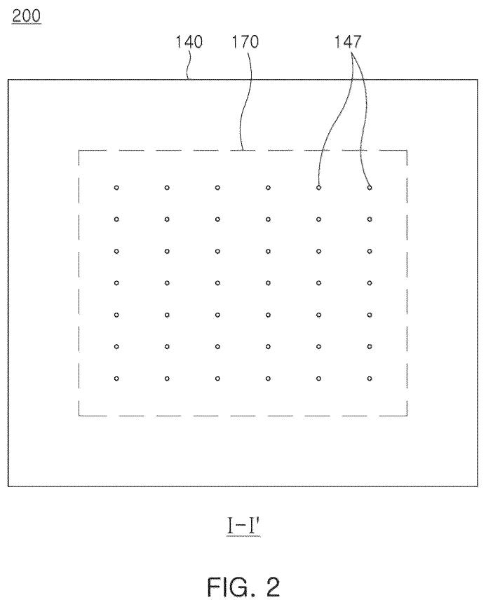

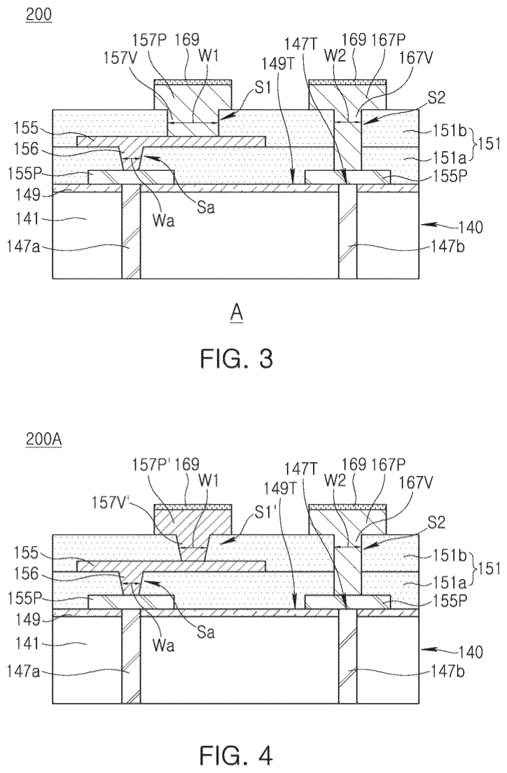

FIG. 1 is a cross-sectional view illustrating a semiconductor package according to one or more example embodiments. FIG. 2 is a plan view illustrating a semiconductor package taken along line I-I′ of FIG. 1 according to one or more example embodiments. FIG. 3 is an enlarged diagram illustrating portion “A” of the semiconductor package illustrated in FIG. 1 according to one or more example embodiments.

Referring to FIGS. 1 and 2, a semiconductor package 200 according to some embodiments may include a first semiconductor chip 140 provided as a base structure, a redistribution structure 150 disposed on the first semiconductor chip 140 and having redistribution layers 155 and redistribution vias 156, and a second semiconductor chip 170 mounted on the redistribution structure 150.

The first semiconductor chip 140 according to some embodiments may include a semiconductor substrate 141 having an active surface 141A and an inactive surface 141B disposed opposite to each other, a device layer 142 disposed on the active surface 141A of the semiconductor substrate 141, first chip pads 145 disposed on the device layer 142, and through-electrodes 147, including, for example, a first through-electrode 147a and a second through-electrode 147b, penetrating through the semiconductor substrate 141 and electrically connected to the first chip pads 145. In some embodiments, a first through-electrode 147a may refer to a through-electrode that is horizontally offset (e.g., not vertically overlapped by) a contact pad 157P of a contact layer 157, and a second through-electrode 147b may refer to a through-electrode that is vertically overlapped by a contact pad 167P of a contact layer 167, as will be described in detail later. As used herein, the phrase “penetrating through” may indicate that a component penetrates entirely through or partially through a layer, other components, etc. Also, an upper surface (the inactive surface 141B) of the semiconductor substrate 141 may include a backside insulating layer 149. For example, the semiconductor substrate 141 may include silicon (Si), germanium (Ge), and gallium arsenide (GaAs). In example embodiments, the active surface 141A may include an active region doped with impurities, and a plurality of active/passive devices (e.g., transistors) may be formed in the active region. The device layer 142 may be configured as a wiring structure including a wiring circuit 142L connected to the devices. The first chip pads 145 may be disposed on the device layer 142, may be connected to the wiring circuit 142L, and may be connected to the through-electrodes 147 through the wiring circuit 142L. As illustrated in FIG. 3 (as well as FIG. 4), the through-electrodes 147 may have an upper end 147T substantially coplanar with the upper surface 149T of the backside insulating layer 149. In some embodiments, the upper end 147T of the through-electrodes 147 may be directly connected to the connection pad 155P (e.g., redistribution pad) of the redistribution structure 150, but embodiments are not limited thereto.

In some embodiments, the first semiconductor chip 140 may further include an additional backside pad connected to the upper end 147T of the through-electrode 147, and an additional backside insulating layer may be provided on the backside insulating layer 149. The additional backside insulating layer may have an upper surface substantially coplanar with an upper surface of the additional backside pad.

In some embodiments, a passivation layer 191 may be provided on a lower surface of the first semiconductor chip 140 (that is, a surface on which the device layer 142 is formed). Through openings of the passivation layer 191, an underbump metallurgy (UBM) layer 192 and the electrical connection metal 195 may be electrically connected to the first chip pads 145. The semiconductor package 200 may be physically and/or electrically connected to an external device (e.g., main board) through the UBM layer 192 and the electrical connection metal 195. The electrical connection metal 195 may be disposed on the UBM layer 118. The electrical connection metal 195 may include solder of a low melting point metal, for example, tin (Sn)-aluminum (Al)-copper (Cu). In some embodiments, a conductive pillar may also be included instead of the UBM layer 192. Alternatively, a redistribution substrate having a redistribution layer similar to the redistribution structure 150 may be further disposed on a lower surface of the first semiconductor chip 140.

In some embodiments, the redistribution structure 150 may be disposed on the first semiconductor chip 140, and may include a redistribution circuit electrically connecting the first semiconductor chip 140 to a second semiconductor chip 170 mounted on an upper surface of the redistribution structure 150.

The redistribution structure 150 may include a plurality of insulating layers 151, redistribution elements such as a redistribution layer 155 and a connection pad 155P, and a redistribution via 156 penetrating through the insulating layer 151 and connecting the redistribution layer 155 and connection pad 155P disposed on different levels to each other. At least one redistribution layer 155 and connection pad 155P disposed on different levels may be connected to each other by the redistribution via 156 and may form a multilayer redistribution circuit. Also, the redistribution structure 150 may include contact layers 157 and 167 for connection to the second semiconductor chip 170.

The contact layers 157 and 167 may correspond to redistribution elements. That is, the contact layers 157 and 167 may form a redistribution circuit together with the redistribution layer 155 and the connection pad 155P. The contact layers 157 and 167 according to some embodiments may be include first contact layers 157 not overlapping (e.g., horizontally offset from) through-electrodes 147 (e.g., through-electrodes such as through-electrode 147a) to be connected in the vertical direction, and second contact layers 167 overlapping through-electrodes 147 (e.g., through-electrodes such as through-electrode 147b) to be connected in the vertical direction.

In some embodiments, the first contact layer 157 and the second contact layer 167 may have different structures for connecting to the corresponding through-electrodes 147 of the first semiconductor chip 140.

Referring to FIG. 3, the redistribution structure 150 according to some embodiments may include connection pads 155P connected to through-electrodes 147, respectively, on the first semiconductor chip 140, a first insulating layer 151a disposed on the first semiconductor chip 140 and covering the connection pads 155P, a redistribution layer 155 disposed on the first insulating layer 151a and extending in the horizontal direction, a redistribution via 156 penetrating through the first insulating layer 151a and connecting the connection pad 155P to the redistribution layer 155, and a second insulating layer 151b disposed on the first insulating layer 151a and covering the redistribution layer 155.

The connection pads 155P may be provided on the through-electrode 147 for connection to the redistribution layer 155. A portion of the connection pads 155P may include a redistribution element for interconnection with the other through-electrodes 147 or to change a position of the connection pad, and accordingly, the connection pads 155P may correspond to a portion of a redistribution circuit.

In some embodiments, the first and second contact layers 157 and 167 may include first and second contact pads 157P and 167P disposed on the second insulating layer 151b. The first and second contact pads 157P and 167P may have a planar arrangement corresponding to the planar arrangement of the second chip pads 175 of the second semiconductor chip 170 to be mounted on the redistribution structure 150.

Each of the first contact layers 157 may include a contact via 157V extending from the first contact pad 157P and penetrating through the second insulating layer 151b. The contact via 157V may connect the first contact pad 157P to the redistribution layer 155. The first contact pad 157P may be connected to the connection pad 155P by the through-electrode 147a through the redistribution layer 155 extending in the horizontal direction.

The second contact layer 167 may include a post via 167V extending from the second contact pad 167P and penetrating through the first and second insulating layers 151a and 151b. The post via 167V may connect the second contact pad 167P to the connection pad 155P by the through-electrode 147b without passing through the redistribution layer 155.

As such, in some embodiments, a connection path of the second contact pad 167P and the connection pad 155P may be implemented by an integrated structure referred to as post via 167V, differently from a connection path of the first contact pad 157P and the connection pad 155P. As opposed to a stack-type structure (having an interfacial surface) formed by two or more metal forming processes (e.g., a plating process), an integrated structure may refer to a structure formed without an interfacial surface by a single metal forming process. Accordingly, as opposed to a general stack-type structure, the integrated post via 167V according to some embodiments may have greater durability against peeling issues due to thermal impact, or the like.

In some embodiments, post via 167V may have a substantially vertical side surface S2. A profile of the side surface S2 of the post via 167V may be determined by a process of forming a hole with respect to the first and second insulating layers 151a and 151b. The hole for the post via 167V may be formed by curing the first and second insulating layers 151a and 151b and processing the layers, and may be formed by, example, dry etching.

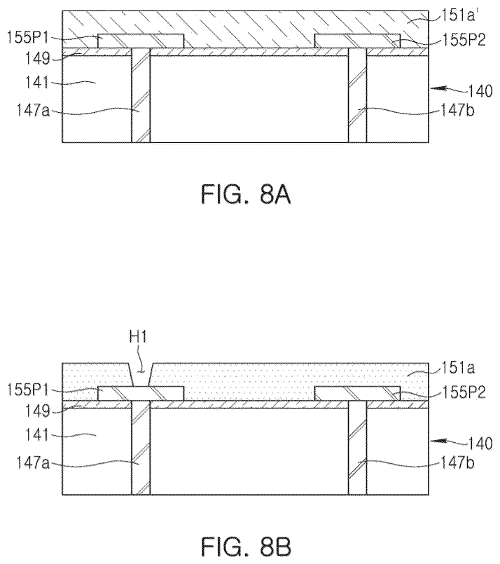

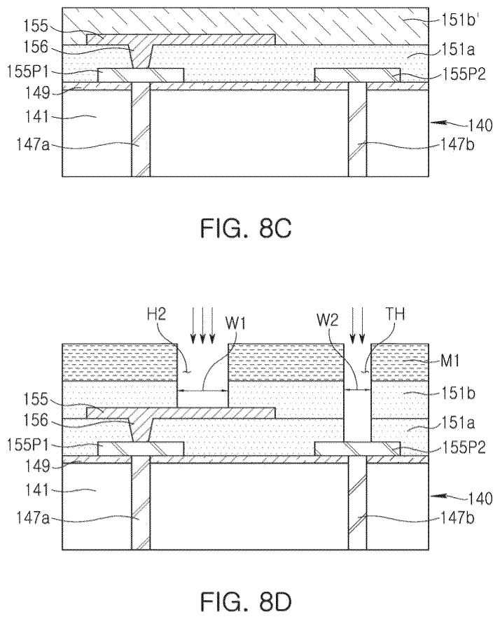

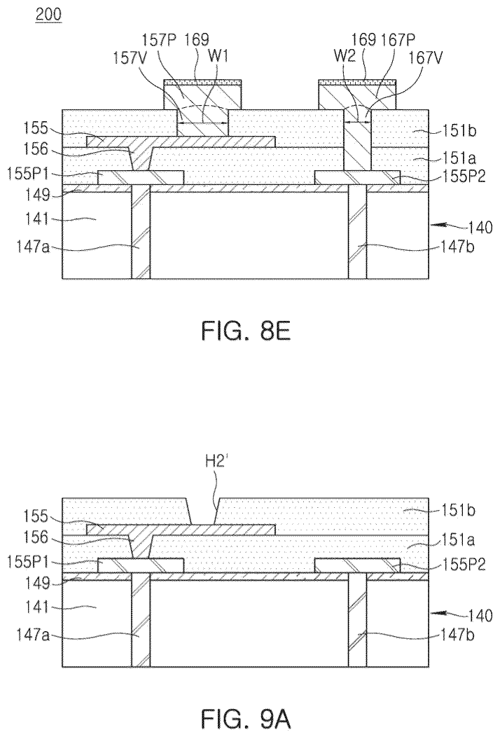

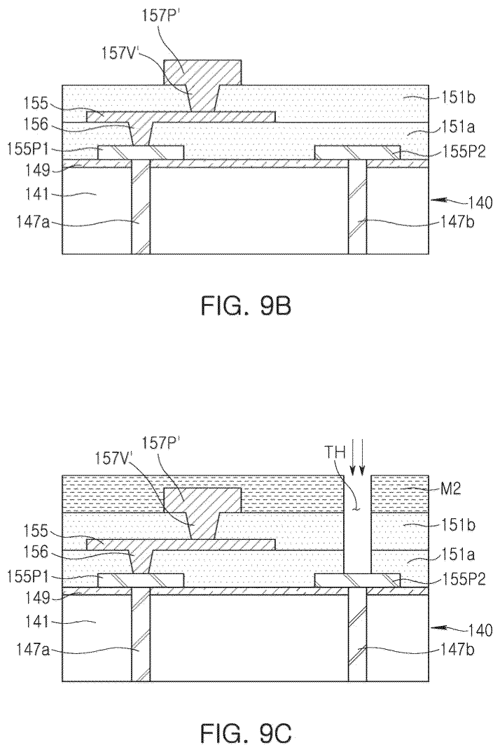

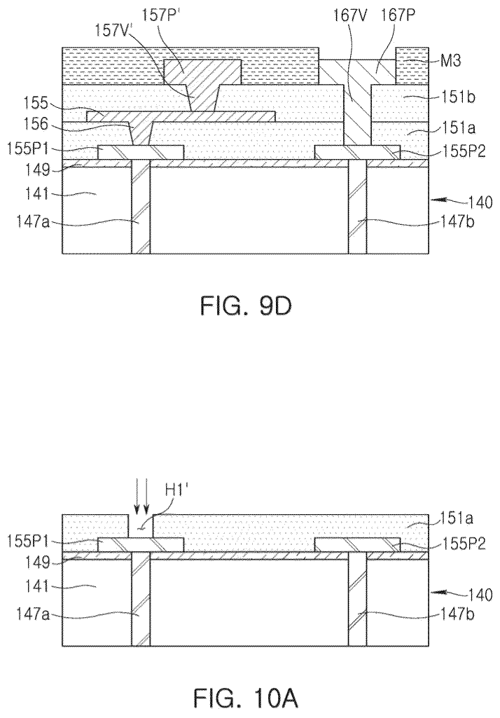

Accordingly, the post via 167V may have a substantially vertical side surface S2. In some embodiments, the contact via 157V may also have a substantially vertical side surface S1 similar to the side surface S2 of the post via 167V. This structure may indicate that the formation of the hole of the contact via 157V may be performed in a manner (e.g., simultaneously) similar to the formation of the hole of the post via 167V (see FIG. 8D). In some embodiments, the redistribution via 156 may have an inclined side surface Sa having a width Wa decreasing in a vertically downward direction, which may be different from the side surfaces S1 and S2 of the contact via 157V and the post via 167V.

In some embodiments, a width W2 of the post via 167V may be greater than the width Wa of the redistribution via. A width W1 of the contact via 157V may be greater than the width W2 of the post via 167V. Since a height of the post via 167V is greater than a height of the contact via 157V, the above-described width condition W1>W2 may be advantageous for forming the post via 167V and the contact via 157V on similar levels through a plating process (see FIG. 8E).

In some embodiments, the redistribution structure 150 may be disposed on the second semiconductor chip 170 and may further include connection pads 155P disposed on the through-electrodes 147, respectively. A portion of the connection pads 155P may be disposed on the through-electrode 147a electrically connected to the first contact pad 157P (that is, on the through-electrode 147s that is not overlapped by (e.g., horizontally offset from) the first contact pad 157P, and at least one other connection pad 155P may be disposed on the through-electrode 147b that is overlapped by the second contact pad 167P and may be directly connected to the post via 167V.

The connection pad 155P, the redistribution layer 155, and the contact layers 157 and 167 disposed on different levels may be connected to each other by the redistribution via 156 and the contact via 157V, and may form a multilayer redistribution circuit. The redistribution structure 150 according to some embodiments is illustrated as a two-layer structure including two insulating layers 151a and 151b, but in other embodiments, the redistribution structure 150 may be implemented to include three or more insulating layers and two or more redistribution layers 155.

In some embodiments, the first and second insulating layers 151a and 151b may use a photosensitive insulating material such as photosensitive insulating (PID) resin. When the first and second insulating layers 151a and 151b are formed of photosensitive insulating resin, the redistribution layer 155 may be formed as a fine pattern using a photolithography process. In some embodiments, at least one of the insulating layers 151 may include a thermosetting resin such as an epoxy resin, or a thermoplastic resin such as polyimide.

The redistribution layer 155 may be disposed on the first insulating layer 151a and may be connected to the connection pad 155P by the redistribution via 156 penetrating through the first insulating layer 151a. On the same level (e.g., the same insulating layer 151a), the redistribution via 156 may be formed with the redistribution layer 155 using the same plating process. For example, the redistribution layer 155 may include a conductive material such as copper (Cu), aluminum (Al), silver (Ag), tin (Sn), gold (Au), nickel (Ni), lead (Pb), titanium (Ti), or alloys thereof. In some embodiments, the redistribution layer 155 may include additional patterns (e.g., ground patterns) having various functions.

The redistribution via 156 may have a tapered structure determined according to the direction of formation. In some embodiments, the redistribution via 156 may have a width gradually decreasing from an upper surface of the redistribution structure 150 to a lower surface of the redistribution structure 150.

Similarly to the redistribution layer 155 and the redistribution via 156, the first contact pad 157P and the contact via 157V may be formed through the same plating process, and the second contact pad 167P and the post via 167V may also be formed through the same plating process. For example, contact layers 157 and 167 may include a conductive material such as copper (Cu), aluminum (Al), silver (Ag), tin (Sn), gold (Au), nickel (Ni), lead (Pb), titanium (Ti), or alloys thereof. In some embodiments, the contact via 157V and the post via 167V may include copper (Cu), and the first contact pad 157P and the second contact pad 167P may include nickel (Ni). In some embodiments, a surface treatment layer 169 may be included on each of the first contact pad 157P and the second contact pad 167P. For example, the surface treatment layer 169 may include gold (Au).

The second semiconductor chip 170 may be mounted on the redistribution structure 150 and may be connected to the redistribution layer 155 through the first and second contact layers 157 and 167. The second semiconductor chip 170 may include second chip pads 175 arranged on the lower surface, and the second chip pads 175 may be connected to the first and second contact pads 157P and 167P, respectively, by conductive bumps 197 such as micro bumps. As illustrated in FIG. 1, a non-conductive film 182 may be disposed in a space between the second semiconductor chip 170 and the redistribution structure 150 to at least partially surround the conductive bumps 197. In some embodiments, the non-conductive film 182 may be replaced with an underfill resin.

In some embodiments, the molding portion 185 may be formed to at least partially surround the second semiconductor chip 170 on the redistribution structure 150. The molding portion 185 may have an upper surface substantially coplanar with an upper surface of the second semiconductor chip 170. For example, the molding portion 185 may include an insulating resin such as an epoxy mold compound (EMC).

As such, in the redistribution structure 150 according to some embodiments, the post via 167V penetrating through the plurality of insulating layers 151a and 151b may be disposed between the second contact pad 167P and the connection pad 155P (or the through-electrode 147), by replacing the stack via structure. As opposed to a general stack via structure, the post via 167V may have an integrated structure without an intermetallic interfacial surface, such that the issue of delamination between metals due to thermal impact may be addressed.

The post vias 167V replacing the stack via structure may be formed in various structures. Also, the formation of post vias 167V may be varied depending on the process of forming the other elements and a method of coupling the elements.

FIGS. 4, 5A, 6A and 6B illustrate semiconductor packages according to various example embodiments, and may be a portion corresponding to FIG. 3 and may be understood as an enlarged diagram illustrating the portion in FIG. 1.

FIG. 4 is a cross-sectional view illustrating a semiconductor package according to one or more example embodiments.

Referring to FIG. 4, a semiconductor package 200A according to some embodiments may be similar to the semiconductor package 200 illustrated in FIGS. 1 to 3 other than the configuration in which a first contact pad 157P′ and a contact via 157V′ may be configured differently from the first contact pad 157P and the contact via 157V in the aforementioned example embodiment. Accordingly, the description in the example embodiment illustrated in FIGS. 1 to 3 may be combined with the description of the aforementioned example embodiment, unless otherwise indicated.

In some embodiments, the side surface S2 of the post via 167V may be substantially vertical, whereas the contact via 157V′ may have a side surface S1′ inclined to have a width W1′ that decreases in a vertically downward direction. The redistribution via 156 may have an inclined side surface Sa having a width Wa that decreases in a vertically downward direction, similar to the side surface of the contact via 157V′.

The first contact pad 157P′ may be formed together with contact via 157V′, and may be formed using different processes from processes of forming the second contact pad 167P and the post via 167V (see FIGS. 9A to 9D). In some embodiments, a width W1′ of contact via 157V′ may be configured without consideration of the width W2 of post via 167V, and in some embodiments, the width W2 of the post via 167V′ may be equal to or greater than the width W1′ of the contact via 157V′.

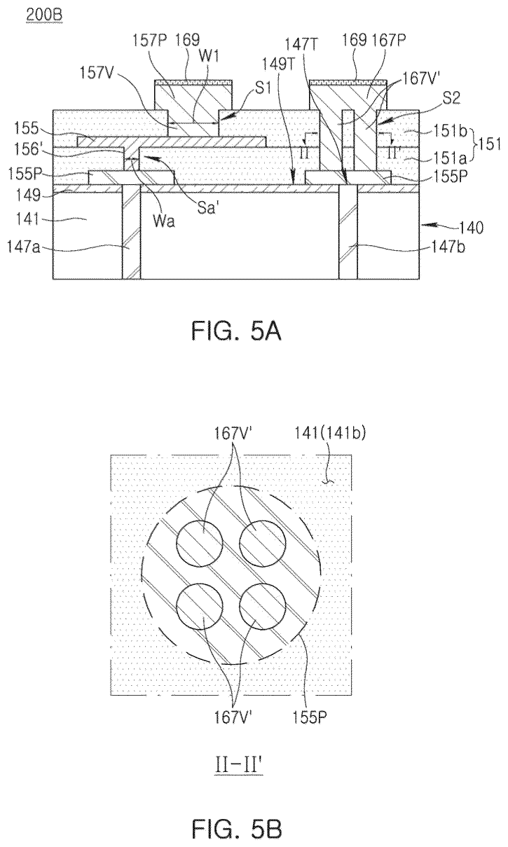

FIG. 5A is a cross-sectional view illustrating a semiconductor package according to one or more example embodiments. FIG. 5B is a plan view illustrating a post via taken along line II-II′ of FIG. 5A, according to one or more example embodiments.

Referring to FIGS. 5A and 5B, a semiconductor package 200B according to some embodiments may be similar to the semiconductor package 200 illustrated in FIGS. 1 to 3 other than the configuration in which a plurality of post vias 167V′ are provided, and the configuration in which the redistribution via 156 may have a vertical side surface. Accordingly, the description of some embodiments illustrated in FIGS. 1 to 3 may be combined with the description of the aforementioned example embodiment, unless otherwise indicated.

In some embodiments, the plurality of post vias 167V′ may be disposed below the second contact pad 167P. The second contact pad 167P overlapping the connection pad 155P may be connected to each other by the plurality of post vias 167V′. Referring to FIG. 5B, four post vias 167V′ are illustrated, but embodiments are not limited thereto, and the plurality of post vias 167V′ may include two, three or more vias.

Each of the post vias 167V′ may have a relatively small width and may enable a stable connection between the second contact pad 167P and the connection pad 155P while reducing the overall volume. Accordingly, when the contact via 157V and the post via 167V′ are formed simultaneously, the contact via 157V may have a volume similar to that of the post via 167V′ even when the width W1 of the contact via 157V slightly increases. That is, the width W1 of the contact via 157V according to some embodiments may be designed to be smaller than the width of the contact via in the embodiment illustrated in FIG. 3.

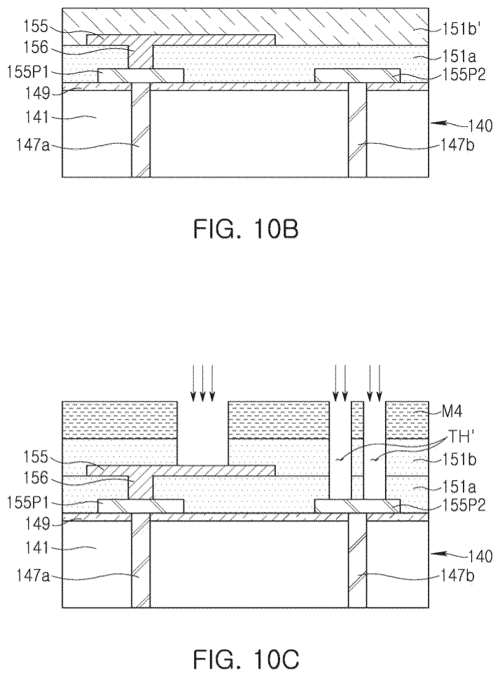

Also, in some embodiments, the redistribution via 156 may have a substantially vertical side surface Sa, similarly to the contact via 157V′ and the post via 167V. A profile of the side surface of this redistribution via 156 may be obtained by curing the first insulating layer 151a (see FIGS. 10A to 10C) and forming a hole thereafter.

In some embodiments, the connection pad 155P may not be provided on the through-electrode 147b overlapped by the second contact pad 167P in the vertical direction.

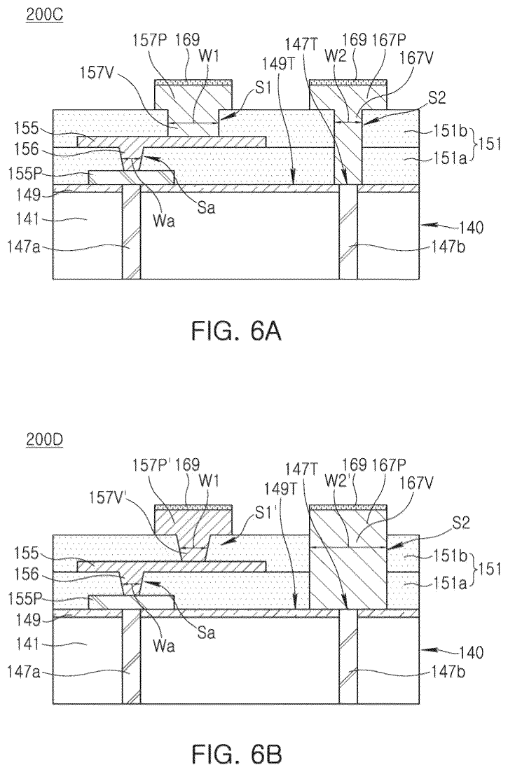

FIGS. 6A and 6B are cross-sectional views illustrating a semiconductor package according to one or more example embodiments.

Referring to FIG. 6A, a semiconductor package 200C according to some embodiments may be configured similarly to the semiconductor package 200 illustrated in FIG. 3 other than the configuration in which the connection pad 155P is not provided on the through-electrode 147b that is overlapped by the second contact pad 167P in the vertical direction.

As such, in some embodiments, the post via 167V may be directly connected to the overlapped through-electrode 147b. The connection pads 155P may be disposed on each of the through-electrodes other than the overlapped through-electrode 147b among the through-electrodes 147 (e.g., through-electrodes 147a that are horizontally offset from the contact pads 157P).

Referring to FIG. 6B, a semiconductor package 200D according to some embodiments may be configured similarly to the semiconductor package 200A illustrated in FIG. 4 other than the configuration in which the connection pad 155P may not be provided on the through-electrode 147b that is overlapped by the second contact pad 167P in the vertical direction and the configuration in which the width of the post via 167V may increase.

In some embodiments, the post via 167V may be directly connected to the overlapped through-electrode 147b. As in FIGS. 6A and 6B, when the connection pad under post via 167V is not provided, the backside insulating layer 149 may be used as an etching stop layer instead of the connection pad in the process of forming a hole for the post via 167V. In some embodiments, a width W2′ of the post via 167V is not limited to the connection pad region, and may sufficiently increase. For example, the width W2′ of post via 167V may be substantially the same as a width of second contact pad 167P.

The redistribution structure 150 disposed between the first and second semiconductor chips 140 and 170, may be connected to the first semiconductor chip 140 through the through-electrodes 147 of the first semiconductor chip 140, and may electrically connect the first semiconductor chip 140 to the second semiconductor chip 170.

As a redistribution substrate, example embodiments disclosed herein may be beneficially applied to packages of various structures having a structure further including a first redistribution structure on a lower surface of the first semiconductor chip 140. In this case, the first redistribution structure may be electrically connected to the second redistribution structures through a vertical connection conductor disposed on an upper surface thereof. Accordingly, the first semiconductor chip 140 connected to the first redistribution structure and the second semiconductor chip 170 connected to the second redistribution structure may be interconnected.

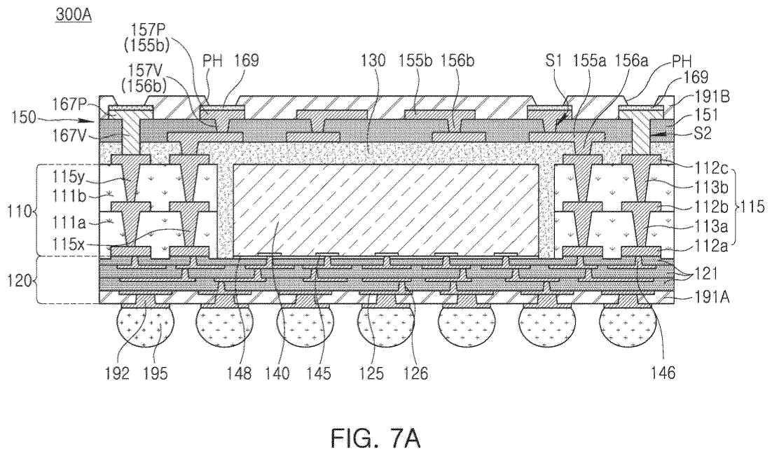

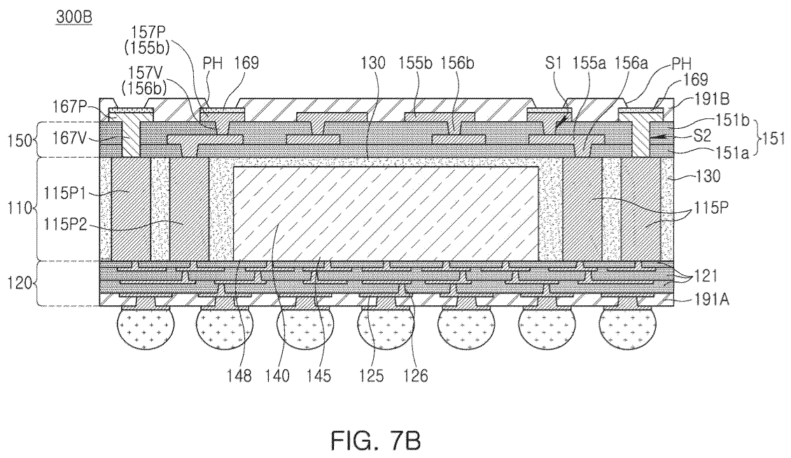

FIGS. 7A and 7B are cross-sectional views illustrating a semiconductor package according to one or more example embodiments.

First, referring to FIG. 7A, a semiconductor package 300A according to some embodiments may include a first redistribution structure 120, a semiconductor chip 140 mounted on the first redistribution structure 120, a molding portion 130 disposed on the first redistribution structure 120 and encapsulating the semiconductor chip 140, and a second redistribution structure 150 disposed on a molding portion 130. Also, the semiconductor package 300A may further include a frame 110, first and second passivation layers 191A and 191B, an UBM layer 192, and an electrical connection metal 195.

The first redistribution structure 120 may include a redistribution layer 125 for redistributing a chip pad 145 of the semiconductor chip 140. The first redistribution structure 120 may be physically and/or electrically connected to an external device (e.g., main board) through the UBM layer 192 and the electrical connection metal 195.

The first redistribution structure 120 may include a plurality of insulating layers 121 and a redistribution layer 125 disposed on each of the insulating layers 121, and redistribution vias 126 penetrating through each of the insulating layers 121 and connecting the chip pad 145 of the first redistribution structure 120 to the redistribution layer 125 on another level. The first redistribution structure 120 according to some embodiments is illustrated as including three insulating layers 121 and three redistribution layers 125 each having a redistribution via 126. In some embodiments, the first redistribution structure 120 may include one or two or more insulating layers 121 and redistribution layers 126.

The frame 110 may be disposed on the first redistribution structure 120 and may include a cavity in which the semiconductor chip 140 is accommodated. A frame 110 may include a wiring structure 115 electrically connecting an upper surface to a lower surface. In some embodiments, the wiring structure 115 may be provided as a vertical connection conductor connecting the first and second redistribution structures 120 and 150 to each other.

The wiring structure 115 according to some embodiments may include three wiring layers, such as first, second, and third wiring layers 112a, 112b, and 112c, and first and second wiring vias 113a and 113b connecting the first, second, and third wiring layers 112a, 112b, and 112c, but embodiments are not limited thereto, and in some embodiments, the wiring structure 115 may have different number of layers and structures. The first redistribution layer 125 (in particular, an uppermost first redistribution layer) may be connected to the chip pad 145 of the semiconductor chip 140 and the wiring structure 115 by the first redistribution via 146.

As such, the wiring structure 115 may be connected to the first redistribution layer 125 of the first redistribution structure 120, and may be electrically connected to the semiconductor chip 140 by the first redistribution structure 120. The frame 110 according to some embodiments may include a first insulating layer 111a, a first wiring layer 112a contacting the first redistribution structure 120 and buried in the first insulating layer 111a, a second wiring layer 112b disposed on a side opposite to the buried side of the first wiring layer 112a of the first insulating layer 111a, a second insulating layer 111b disposed on the first insulating layer 111a and covering the second wiring layer 112b, and a third wiring layer 112c disposed on the second insulating layer 111b. The first, second, and third wiring layers 112a, 112b, and 112c may be electrically connected to each other through the first to second wiring vias 113a and 113b penetrating through the first and second insulating layers 111a and 111b, respectively.

In some embodiments, the second redistribution structure 150 may be disposed on the semiconductor chip 140. Similarly to the first redistribution structure 120, the second redistribution structure 150 may include an insulating layer 151, redistribution layers 155a and 155b disposed on different levels, and redistribution vias 156a and 156b penetrating through the insulating layer 151 and connecting to the second redistribution layers 155a and 155b. Specifically, the lower redistribution layer 155a may be connected to the wiring structure 115 (particularly, the third wiring layer 112c) through a lower redistribution via 156a penetrating through a region of the molding portion 130. The upper redistribution layer 155b may be connected to the lower redistribution layer 155a through the upper redistribution via 156b penetrating through the insulating layer 151.

In some embodiments, the first and second contact layers 157 and 167 may include first and second contact pads 157P and 167P, respectively, disposed on the insulating layer 151. In some embodiments, the first contact layer 157 may be formed with the upper redistribution layer 155b and the upper redistribution via 156b. Additional semiconductor chips mounted on the second redistribution structure 150 and connected to the first and second contact pads 157P and 167P may not be provided.

The wiring structure 115 may include a first vertical connection conductor 115x that is horizontally offset from the contact pad 157P (i.e., that is not overlapped by the contact pad 157P), and a second vertical connection conductor 115y that is vertically overlapped by the contact pad 167P.

A contact via 157V may extend from the first contact pad 157P and may penetrate through the insulating layer 151. The contact via 157V may connect the first contact pad 157P to the upper redistribution layer 155b. The first contact pad 157P may be connected to the third wiring layer 112c on the non-overlapped wiring structure 115 (e.g., vertical connection conductor 115x) through the second redistribution layers 155a and 155b extending in the horizontal direction.

A post via 167V may extend from the second contact pad 167P and may penetrate through a region of the insulating layer 151 and the molding portion 130. The post via 167V may connect the second contact pad 167P to the third wiring layer 112c disposed on the overlapped wiring structure 115 (e.g., vertical connection conductor 115y) without passing through the second redistribution layers 155a and 155b.

As such, in some embodiments, the post via 167V connecting the second contact pad 167P to the third wiring layer 112c may have an integrated structure without an interfacial surface, such that the post via 167V may have greater durability against peeling issues due to thermal impact.

Also, the post via 167V may have a substantially vertical side surface. In some embodiments, as described in FIG. 4, the contact via 157V may have an inclined side surface, differently from the side surface S2 of the post via 167V. Similar to the second redistribution vias 156a and 156b, the contact via 157V may have an inclined side surface having a width that decreases in a vertically downward direction.

A semiconductor package according to some embodiments may include first and second passivation layers 191A and 191B. The first and second passivation layers 191A and 191B may protect the first and second redistribution structure 120 and 150 from external physical and chemical damages. The first passivation layer 191A may be disposed on a lower surface of the first redistribution structure 120 and may include a plurality of first openings. UBM layers may be disposed on the first passivation layer 191A and may be connected to the first redistribution layer 125 through the openings, respectively. The second passivation layer 191B may be disposed on an upper surface of the second redistribution structure 150 and may include a plurality of second openings PH which opens the pad region. For example, the first and second passivation layers 191A and 191B may include an insulating material such as prepreg, Ajinomoto build-up film (ABF), FR-4, bismaleimide triazine (BT) solder resist, or PID.

The semiconductor chip 140 according to some embodiments may include a semiconductor substrate having an active surface on which various devices are formed, chip pads 145 connected to the various devices, and a passivation film 148 protecting the active surface. The semiconductor substrate 141 may include, for example, silicon (Si), germanium (Ge), or gallium arsenide (GaAs). The chip pad 145 may be an element for electrically connecting the semiconductor chip 140 to another element (the first redistribution layer 125), and may include, for example, aluminum (Al) or copper (Cu). The passivation film 148 may include an oxide film and/or a nitride film.

The semiconductor chip 140 may be a processor chip. For example, the semiconductor chip 140 may include a microprocessor, a graphics processor, a signal processor, a network processor, a chipset, an audio codec, a video codec, an application processor or a system on chip, an application-specific integrated circuit (IC) (ASIC), or a power management IC (PMIC), but some embodiments thereof is not limited thereto. For example, the microprocessor may include a single core or multiple cores. In some embodiments, the semiconductor chip 140 may be implemented as a volatile memory chip and/or a non-volatile memory chip. For example, the volatile memory chip may include a dynamic random access memory (DRAM), a static RAM (SRAM), a thyristor RAM (TRAM), a zero capacitor RAM (ZRAM), or a twin transistor RAM (TTRAM). Also, the non-volatile memory chip may include, for example, a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano-floating gate memory, a holographic memory, a molecular electronics memory, or an insulator resistance change memory.

The molding portion 130 may protect the frame 110 and the semiconductor chip 140. A material of the molding portion 130 may include, for example, a thermosetting resin such as epoxy resin or a thermoplastic resin such as polyimide. In some embodiments, the molding portion 130 may be formed of EMC.

In the aforementioned example embodiments, the vertical connection conductor connected to the redistribution layer of the redistribution structure and connected to the upper surface of the semiconductor package may be implemented in the form of a wiring structure of the frame, but the vertical connection conductor may be disposed on the redistribution structure without a frame structure and may also be provided as a conductive post penetrating through the molding portion. These example embodiments are illustrated in FIG. 7B.

Referring to FIG. 7B, a semiconductor package 300B according to some embodiments may be configured similarly to the semiconductor package 300A illustrated in FIG. 7A other than the configuration in which a conductive post 115P may be provided instead of a frame, and the configuration in which the second redistribution structure 150 may include two insulating layers 151a and 151b. Accordingly, the description of some embodiments illustrated in FIGS. 1 to 3 and FIG. 7A may be combined with the description of the aforementioned example embodiment, unless otherwise indicated.

The semiconductor package 300B according to some embodiments may be a semiconductor package formed on a wafer level. The semiconductor package 300B may include a vertical connection conductor for interconnecting the first redistribution structure 120 to the second redistribution structure 150, and may be provided as a conductive post 115P such as a copper (Cu) post. The conductive post 115P may be formed to penetrate through the molding portion 130 encapsulating the semiconductor chip 140. Through the conductive post 115P, the first redistribution layer 125 and the second redistribution layer 155 may be electrically connected to each other. In some embodiments, the conductive post 115P may have an upper end substantially coplanar with an upper surface of the molding portion 130.

In some embodiments, the second redistribution structure 150 may be disposed on the molding portion 130. The second redistribution structure 150 may include insulating layers 151a and 151b, second redistribution layers 155a and 155b disposed on the insulating layers 151a and 151b respectively, and second redistribution vias 156a and 156b penetrating through the insulating layers 151a and 151b and connecting to the second redistribution layers 155a and 155b, respectively. Specifically, the lower redistribution layer 155a may be connected to the conductive post 115P through the lower redistribution via 156a penetrating through the lower insulating layer 151a. The upper redistribution layer 155b may be connected to the lower redistribution layer 155a through the upper redistribution via 156b penetrating through the upper insulating layer 151b.

In some embodiments, the first and second contact layers 157 and 167 may include first and second contact pads 157P and 167P, respectively, disposed on the upper insulating layer 151b. In some embodiments, the contact via 157V may extend from first contact pad 157P and may penetrate through the upper insulating layer 151b. The contact via 157V may connect the first contact pad 157P to the upper redistribution layer 155b. The first contact pad 157P may be connected to the conductive post 115P1 through the second redistribution layers 155a and 155b extending in the horizontal direction. That is, the conductive post 115P1 may be horizontally offset from the contact pad 157P, such that the conductive post 115P1 is not overlapped by the contact pad 157P.

The post via 167V may extend from the second contact pad 167P and may penetrate through the lower and upper insulating layers 151a and 151b. The post via 167V may connect the second contact pad 167P to the conductive post 115P2 without passing through the second redistribution layers 155a and 155b. That is, the contact pad 167P may vertically overlap the conductive post 115P2.

As such, in some embodiments, the post via 167V connecting the second contact pad 167P to the third wiring layer 112c may have an integrated structure without an interfacial surface, such that the post via 167V may have greater durability against peeling issues due to thermal impact.

FIGS. 8A to 8E are cross-sectional views illustrating a method of manufacturing a semiconductor package according to one or more example embodiments. The manufacturing method according to some embodiments may be understood as the manufacturing process of the semiconductor package 200 illustrated in FIG. 3.

Referring to FIG. 8A, a first semiconductor chip 140 having a first connection pad 155P1 and a second connection pad 155P2 may be prepared, and a first insulating layer 151a′ may be formed on the first semiconductor chip 140 using an uncured photosensitive insulating material.

In some embodiments, the first insulating layer 151a may be configured as an uncured insulating layer and may include, for example, a photosensitive insulating material such as a PID. Connection pads including a first connection pad 155P1 and the second connection pad 155P2 may be provided on a through-electrode 147, and in some embodiments, the connection pad 155P1 may include a redistribution element for interconnection with another through-electrode 147 or for changing the position of the pad, and may thus be understood as a portion of the redistribution circuit.

The structure to which some embodiments may be applied is not limited to a semiconductor chip having a through-electrode, and may also be usefully applied to various structures in which a redistribution structure for interconnection is disposed on an upper surface thereof in the vertical direction. For example, a lower package structure having vertical connection conductors (e.g., structures 115 and 115P) illustrated in FIGS. 7A and 7B may be included.

Thereafter, referring to FIG. 8B, a first hole H1 connected to the first connection pad 155P1 may be formed through the first insulating layer 151a′ using a photolithography process.

The first insulating layer 151a′ may be cured (to form the first insulating layer 151a) by a photolithography process (exposure and development). Also, the second connection pad 155P2 may still be covered by the first insulating layer 151a. The second connection pad 155P2 may be a connection pad overlapping a contact pad (the second contact pad 167P in FIG. 8E) connected thereto in the vertical direction in a subsequent process.

Thereafter, referring to FIG. 8C, the first hole H1 may be filled by a redistribution via 156. A redistribution layer 155 connected to the redistribution via 156 may be formed on the redistribution via 156 filled in the first hole H1 and the first insulating layer 151a, and a second insulating layer 151b′ may be formed on the first insulating layer 151a to cover the redistribution layer 155.

The redistribution layer 155 and the redistribution via 156 may be formed together by a plating process such as electrolytic plating. The second insulating layer 151b′ may be configured as an uncured insulating layer and, for example, may include a photosensitive material similar to the first insulating layer, but some embodiments thereof is not limited thereto.

Thereafter, referring to FIG. 8D, the second insulating layer 151b′ may be cured (to form second insulating layer 151b), and a second hole H2 for a contact via and a through-hole TH for a post via may be formed using a mask M1.

The second hole H2 may penetrate through the second insulating layer 151b and may be connected to a region of the redistribution layer 155. The through-hole TH may penetrate through the first and second insulating layers 151a and 151b and may be connected to the second connection pad 155P2. The second hole H2 and the through-hole TH may be formed simultaneously in the cured first and second insulating layers 151a and 151b using a dry etching process. As such, the second hole H2 and the through-hole TH obtained by the dry etching process may have substantially vertical sidewalls, differently from a first hole H1 which has inclined sidewalls. These sidewalls may define profiles of side surfaces of the contact via (“157V” in FIG. 8E) and the post via (“167V” in FIG. 8E) to be formed in a subsequent process, respectively.

In the process of forming the second hole H2, a redistribution layer 155 may act as an etching stop layer. Also, during the process of forming the through-hole TH, the connection pad 155P may act as an etching stop layer. Through the etching stop layer, the second hole H2 and the through-hole TH having different depths may be formed. The second hole H2 may be formed to have a width W1 larger than a width W2 of the through-hole TH.

Thereafter, referring to FIG. 8E, the second hole H2 and the through-hole TH may be filled with metal, thereby forming the first and second contact layers 157 and 167.

The processes of forming the first and second contact layers 157 and 167 may be performed simultaneously using a plating process such as electrolytic plating. The first contact layer 157 may include a contact via 157V filled in the second hole H2 and a first contact pad 157P formed on the second insulating layer 151b and connected to the contact via 157V. The second contact layer 167 may include a post via 167V filled in the through-hole TH and a second contact pad 167P formed on the second insulating layer 151b and connected to the post via 167VP. The second hole H2 and the through-hole TH may be filled simultaneously and may form the contact via 157V and the post via 167V. The second hole H2 may form the contact via 157V and the post via 167V on similar levels (the dotted line) by adjusting the width of the through-hole TH.

In some embodiments, the contact via 157V and the post via 167V may include a metal different from that of the first and second contact pads 157P and 167P. For example, the contact via 157V and the post via 167V may include copper, and the first and second contact pads 157P and 167P may include nickel. Also, a surface treatment layer 169 may include gold (Au).

FIGS. 9A to 9D are cross-sectional views illustrating a method of manufacturing a semiconductor package according to one or more example embodiments. The manufacturing method according to some embodiments may be understood as the process of manufacturing the semiconductor package 200A illustrated in FIG. 4.

The processes in FIG. 9A may be subsequently performed after the series of processes in FIGS. 8A to 8C, and a second hole H2′ may be formed using a photolithography process while the second insulating layer 151 in an uncured state. The second hole H2′ may penetrate through the second insulating layer 151b and may be connected to a region of the redistribution layer 155. The second insulating layer 151a may be cured through this photolithography process (exposure and development). Since the second hole H2′ in some embodiments is formed by a photolithography process, the second hole H2′ may have an inclined sidewall, differently from the second hole H2 in FIGS. 8A-8E.

Thereafter, referring to FIG. 9B, a contact via 157V′ may fill the second hole H2′, and a first contact pad 157P′ connected to the contact via 157V′ may be formed on the second insulating layer 151b. The contact via 157V′ and the first contact pad 157P′ may be formed by a plating process, similarly to the formation of the redistribution layer 155 and the redistribution via 156.

Thereafter, referring to FIG. 9C, a through-hole TH connected to a second connection pad 155P2 may be formed using a mask M2.

This process may be performed by a dry etching process. The through-hole TH may penetrate through the first and second insulating layers 151a and 151b and may be connected to the second connection pad 155P2. The through-hole TH formed through the dry etching process may have a substantially vertical sidewall, differently from the inclined sidewall of the second hole H2′ formed in the previous process.

Thereafter, referring to FIG. 9D, a second contact layer 167 may be formed on the through-hole TH using a mask M3. The second contact layer 167 may be disposed on the post via 167V filled in the through-hole TH and the second insulating layer 151b, and may form a second contact pad 167P connected to the post via 167V.

FIGS. 10A to 10C are cross-sectional views illustrating a method of manufacturing a semiconductor package according to one or more example embodiments. The manufacturing method according to some embodiments may be understood as the process of manufacturing the semiconductor package 200B illustrated in FIG. 5A.

The process in FIG. 10A may be understood as a process subsequent to the process in FIG. 9A. Specifically, a first insulating layer 151a may be formed on a first semiconductor chip 140 to cover first and second connection pads 155P1 and 155P2, and the first insulating layer 151a may be cured. Thereafter, using a dry etching process, a first hole H1′ penetrating through the first insulating layer 151a and connected to the first connection pad 155P1 may be formed. The first hole H1′ formed in this process may have a substantially vertical sidewall.

Thereafter, referring to FIG. 10B, a redistribution via 156 may fill the first hole H1″, a redistribution layer 155 connected to the redistribution via 156 may be formed on the redistribution via 156 filled in the first hole H1′, and the first insulating layer 151a, and a second insulating layer 151b′ may be formed on the first insulating layer 151a to cover the redistribution layer 155.

Thereafter, referring to FIG. 10C, the second insulating layer 151b′ may be cured (to form second insulating layer 151b), and, using a mask M4, a second hole H2 penetrating through the second insulating layer 151b and connected to a region of the redistribution layer 155, and through-holes TH′ penetrating through the first and second insulating layers 151a and 151b and connected to the second connection pad 155P2 may be formed. The mask M4 may include an open region for the plurality of through-holes TH′ in a via region. The second hole H2 and the through-hole TH′ may be formed using a dry etching process, and each of the holes may have a substantially vertical sidewall. Thereafter, by performing a plating process, the semiconductor package 200B having the first and second contact layers illustrated in FIGS. 5A and 5B may be formed.

According to example embodiments, a post via penetrating through the plurality of insulating layers may be disposed between the contact pad and the connection pad (or the through-electrode) vertically overlapping each other. As opposed to a general stack via structure, the post via may have an integrated structure without an intermetallic interfacial surface, such that the delamination issue may be addressed even when stress is concentrated.

Each of the embodiments provided in the above description is not excluded from being associated with one or more features of another example or another embodiment also provided herein or not provided herein but consistent with the disclosure.

While example embodiments have been illustrated and described above, it will be understood to those skilled in the art that modifications and variations could be made without departing from the scope of the present disclosure as defined by the appended claims.

1. A semiconductor package comprising:
a first semiconductor chip comprising:
a semiconductor substrate having an active surface and an inactive surface;
a device layer on the active surface;
first chip pads on the device layer; and
a first through-electrode and a second through-electrode, wherein the first through-electrode and the second through-electrode penetrate the semiconductor substrate, at least one of the first chip pads is connected to the first through-electrode, and at least one of the first chip pads is connected to the second through-electrode;
a redistribution structure comprising:
a redistribution layer on the inactive surface of the semiconductor substrate; and
a redistribution via connected to the redistribution layer;
contact pads on an upper surface of the redistribution structure; and
a second semiconductor chip on the redistribution structure and comprising second chip pads connected to the contact pads,
wherein the contact pads comprise a first contact pad connected to the first through-electrode through the redistribution layer and a second contact pad vertically overlapping the second through-electrode,
wherein the redistribution structure further comprises at least one post via penetrating the redistribution structure and connecting the second contact pad to the second through-electrode, and
wherein the first contact pad comprises a contact via connected to the redistribution layer.

2. The semiconductor package of claim 1, wherein the redistribution structure further comprises a first insulating layer on an upper surface of the first semiconductor chip, and a second insulating layer on the first insulating layer,
wherein the redistribution layer is on the first insulating layer, and
wherein the redistribution via penetrates the first insulating layer and connects the redistribution layer to the first through-electrode.

3. The semiconductor package of claim 2, wherein the first contact pad and the second contact pad are on the second insulating layer,
wherein the contact via penetrates the second insulating layer and connects the first contact pad to the redistribution layer, and
wherein the at least one post via penetrates the first insulating layer and the second insulating layer.

4. The semiconductor package of claim 1, wherein each of the at least one post via and the contact via has a vertical side surface.

5. The semiconductor package of claim 4, wherein a width of the at least one post via is smaller than a width of the contact via.

6. The semiconductor package of claim 4, wherein the redistribution via has a width that decreases vertically downward.

7. The semiconductor package of claim 1, wherein the at least one post via has a vertical side surface, and
wherein the contact via has an inclined side surface such that the contact via has a width that decreases vertically downward.

8. The semiconductor package of claim 7, wherein the redistribution via has an inclined side surface such that the redistribution via has a width that decreases vertically downward.

9. The semiconductor package of claim 7, wherein the at least one post via comprises a plurality of post vias connected to the second contact pad.

10. The semiconductor package of claim 1, wherein the redistribution via has a vertical side surface.

11. The semiconductor package of claim 1, wherein the at least one post via has a width that is greater than a width of the redistribution via.

12. The semiconductor package of claim 1, wherein the at least one post via has an integrated structure.

13. The semiconductor package of claim 1, wherein the first semiconductor chip further comprises a backside insulating layer having an upper surface that is substantially coplanar with an upper surface of the first through-electrode and an upper surface of the second through-electrode.

14. The semiconductor package of claim 13, wherein the redistribution structure further comprises a first connection pad and a second connection pad on the first through-electrode and the second through-electrode, respectively,
wherein the first connection pad is connected to the redistribution layer through the redistribution via and is connected to the first contact pad through the redistribution layer, and
wherein the second connection pad is connected to the second contact pad through the at least one post via.

15. (canceled)

16. A semiconductor package comprising:
a first redistribution structure comprising a first redistribution layer and a first redistribution via connected to the first redistribution layer;
a semiconductor chip on the first redistribution structure and comprising chip pads connected to the first redistribution layer;
a molding portion on the first redistribution structure and at least partially surrounding the semiconductor chip;
a second redistribution structure on the molding portion, the second redistribution structure comprising a second redistribution layer and a second redistribution via connected to the second redistribution layer;
contact pads on an upper surface of the second redistribution structure; and
a first vertical connection conductor and a second vertical connection conductor that are on the first redistribution structure and connect the first redistribution layer to the second redistribution layer,
wherein the contact pads comprise a first contact pad connected to the first vertical connection conductor through the second redistribution layer, the first contact pad being horizontally offset from the first vertical connection conductor, and a second contact pad vertically overlapping the second vertical connection conductor,
wherein the first contact pad comprises a contact via connected to the second redistribution layer, and
wherein the second redistribution structure further comprises a post via connecting the second contact pad to the second vertical connection conductor.

17. The semiconductor package of claim 16, wherein each of the post via and the contact via has a vertical side surface, and
wherein the second redistribution via has a width that decreases vertically downward.

18. The semiconductor package of claim 17, wherein a width of the post via is smaller than a width of the contact via.

19. The semiconductor package of claim 16, wherein the post via has an integrated structure having a vertical side surface,
wherein the contact via has an inclined side surface such that the contact via has a width that decreases vertically downward, and
wherein the second redistribution via has an inclined side surface such that the second redistribution via has a width that decreases vertically downward.

20. The semiconductor package of claim 16, further comprising:
a frame on the first redistribution structure and at least partially surrounding the semiconductor chip,
wherein each of the first vertical connection conductor and the second vertical connection conductor comprises a wiring structure connecting an upper surface of the frame to a lower surface of the frame.

21. (canceled)

22. (canceled)

23. A semiconductor package comprising:
a first semiconductor chip comprising:
a semiconductor substrate having an active surface and an inactive surface opposite to the active surface;
a device layer on the active surface;
first chip pads on the device layer; and
through-electrodes penetrating the semiconductor substrate and connected to the first chip pads;
a redistribution structure on the inactive surface of the first semiconductor chip;
a first contact pad and a second contact pad that are on an upper surface of the redistribution structure, wherein the second contact pad vertically overlaps one of the through-electrodes; and
a second semiconductor chip on the redistribution structure and comprising a first second chip pad connected to the first contact pad, and a second chip pad connected to the second contact pad,
wherein the redistribution structure comprises:
a first insulating layer on an upper surface of the first semiconductor chip;
a redistribution layer on the first insulating layer;
a redistribution via penetrating the first insulating layer and connecting the redistribution layer to the through-electrodes; and
a second insulating layer on the first insulating layer and at least partially covering the redistribution layer,
wherein the first contact pad is on the second insulating layer and comprises a contact via penetrating the second insulating layer and connected to the redistribution layer, and
wherein the second contact pad is on the second insulating layer and comprises a post via penetrating the first insulating layer and the second insulating layer and connecting to the one through-electrode that is vertically overlapped by the second contact pad.

24. (canceled)

25. (canceled)
